(19) United States
(12) Patent Application Publication
(10) Pub. No.: US 2025/0219350 A1
(43) Pub. Date: Jul. 3, 2025

(54) OPTICAL SYSTEM-IN-PACKAGE, AND OPTICAL MODULE AND OPTICAL TRANSCEIVER USING SAME

(71) Applicant: LIPAC CO., LTD., Seoul (KR)

(72) Inventor: Seong Wook CHOI, Seoul (KR)

(21) Appl. No.: 18/849,468

(22) PCT Filed: Mar. 23, 2023
(86) PCT No.: PCT/KR2023/003868

§ 371 Date: Sep. 20, 2024

(30) Foreign Application Priority Data
Mar. 23, 2022 (KR) 10-2022-0036215

(51) Int. Cl. H01S 5/0239; H01S 5/02253; H01S 5/02315; H01S 5/024

(52) U.S. Cl. CPC H01S 5/0239; H01S 5/02253; H01S 5/02315; H01S 5/02438; H01S 5/02469

(57) ABSTRACT

Provided is an optical system-in-package where an edge-type light-emitting laser diode and a driver IC are included in the package, and a planar light circuit chip is assembled directly on a redistribution layer or through a main printed circuit board, and an optical module and an optical transceiver using same. The optical system-in-package includes a mold body having planar first and second surfaces on the upper and lower portions of the mold body, respectively, a submount molded inside the mold body and having a side surface having an inclined surface, an edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to outside.

### TECHNICAL FIELD

The present invention relates to an optical module using an optical system-in-package (O-SIP), and more specifically, to an optical module and an optical transceiver using an O-SIP, in which the O-SIP includes an edge-type light-emitting laser diode and a driver integrated circuit (IC) in a mold body package and a planar light circuit (PLC) is assembled directly or through a printed circuit board (PCB) on a redistribution layer.

### BACKGROUND ART

Semiconductor chips may be used to manufacture light receiving devices capable of reacting to light or light-emitting devices emitting light, as well as serving as a logic or driving IC. These optical devices are used in various fields, such as optical transceivers in charge of optical connections between servers, or modules that transmit image data between TVs and set-top boxes, or between virtual reality (VR) glasses and graphics processing units (GPUs).

Further, other applications of the optical devices may be used in a proximity sensor, a time of flight (TOF) sensor, a light detection and ranging (LIDAR) device, and the like, which include a light-emitting device.

Optical devices should be used together with electronic devices that drive or interface the optical devices, thereby converting optical signals into electronic signals. For example, in the field of transmitting optical data, an optical device and an electronic device may be used together for a module for converting an optical signal into a digital signal. As another example, in the optical sensor field, a device for converting characteristics of received light into image data or depth data may be used together with an optical device.

In all of the above conventional applications, a plurality of chips are mounted using a printed circuit board (PCB) in which a wiring pattern is mostly manufactured and connected by wire-bonding. This is generally called a chip-on-board (CoB) type package.

In addition, instead of a package using a PCB, an optical/electric device may be packaged at a wafer level using a semiconductor package method based on a fan-out wafer level package (FOWLP) process, which is a technology that may increase performance by using a high-precision redistribution layer (RDL) while producing an ultra-thin package.

In addition, optical communication systems are often used to transmit data in a variety of systems, such as telecommunication systems and data communication systems. The electrical telecommunication systems often involve the transmission of data over a wide geographical distance ranging from a few miles to thousands of miles. The data communication systems often involve the transmission of data through a data center. Such systems include the transmission of data over distances ranging from a few meters to hundreds of meters.

In general, short-distance optical communication within 300 m is implemented using a multimode vertical-cavity surface-emitting laser (VCSEL) as a light-emitting element, but VCSEL cannot transmit long-distance, for example, 10 Km or longer.

That is, a backbone of an optical network that requires long-distance transmission of large amounts of data over 300 m to several tens of km, or an optical transmission module (such as TOSA) of at least a 100G-class optical transceiver that is employed within a data center requires performing a wavelength multiplexer (WDM MUX) function for collecting signals of four channels having different wavelengths (frequencies) and transmitting them to one optical fiber.

The wavelength multiplexer (WDM MUX) requires alignment of four edge-type light-emitting devices in a single mode capable of long-distance transmission and arrayed waveguide grating (AWG) having a single-mode waveguide for WDM transmission.

In particular, when a long-distance or high-power laser diode is used, the long-distance or high-power laser diode outputs a laser at a single mode, and in most cases, the long-distance or high-power laser diode has an edge-type light-emitting laser diode form in which light is emitted to the side of the chip. Therefore, there is a need for a method capable of effectively packaging such a device.

For optical alignment of an edge-type light-emitting device that emits light in the edge direction of a chip capable of long-distance transmission and an AWG having a single mode waveguide, optical alignment in sub-micron units should be made in all x, y, and z directions.

However, it is difficult to fully solve the height tolerance by inter-element wiring to solve the assembly difficulty while using passive alignment by automating optical alignment in all directions between edge-type light-emitting devices, optical components (i.e., AWG) and optical fibers at a wafer level.

In addition, in many cases, an optical phase array (OPA) for light detection and ranging (LIDAR) sensors or a modulator for optical communication is produced using silicon photonics, which should be assembled together with laser diodes and laser driving circuits.

### DISCLOSURE

### Technical Problem

In a case in which an edge-type light-emitting laser diode is used to perform an optical/electric package by using a long-distance or high-power laser diode, a task to be solved by the present invention is to design a structure in which an optical coupling may be easily performed using silicon photonics (SiPh) forming a PLC chip, optical components each having an optical function or optical fibers, and to implement a performance improvement and a low power by co-packaging laser diodes and electronic driving devices.

When optical coupling is performed using a silicon photonics chip, a grating coupler is mainly used. In this case, light should be incident on the surface of the silicon photonics chip in an almost vertical direction (or between 80 and 90 degrees). However, in the case of a single mode laser diode, since light comes out horizontally from the surface of the chip, more lenses and mirrors should be used to change the direction of light, which increases the complexity and cost of assembly.

In addition, a driving chip should be connected for the electrical operation of the silicon photonics chip, and the external driving chip should have a very short wiring distance to enable excellent performance without signal loss.

Even though a silicon photonics chip is not used, it is often necessary to connect edge-type light-emitting laser diodes with optical components/optical fibers. Likewise, even in this case, complex optical systems such as lenses are often required, and this invention proposes a packaging method that easily and accurately implements integration between these parts.

Moreover, it is very important to design a heat dissipation structure when using optical chips such as edge-type light-emitting laser diodes, and since not only does optical chips generate a lot of heat, but light-emitting conditions or light-receiving conditions of optical chips are often sensitive to temperature, heat dissipation design is a very important part. In all of the existing methods of using CoB or semiconductor packaging, if a heat dissipation structure (for example, a structure connected to a heat sink or metal housing) is placed on a light-emitting surface of the package, the optical path is hidden by the heat dissipation structure and thus, the heat dissipation structure is generally placed on the other side of the light-emitting surface of the package.

Therefore, most of the heat dissipation path consists of a surface where the terminal pad of the package is located, and in this case, since the surface where the terminal pad of the package is formed is connected to a main PCB of an optical transceiver, most of the heat dissipation of the package occurs through a thermal via of the main PCB. Therefore, the conventional method has a problem in that the heat dissipation path between the heat dissipation structure and the chip is interrupted by the PCB.

The present invention provides an optical module and an optical transceiver using an optical system-in-package (O-SIP), in which the O-SIP includes an edge-type light-emitting laser diode and a driver IC in the package, and a planar light circuit (PLC) is assembled directly or through a printed circuit board (PCB) on a redistribution layer (RDL).

### Technical Solution

According to an aspect of the present invention, there is provided an optical system-in-package (O-SIP) including a mold body having a first surface and a second surface which are flat on an upper portion and a lower portion of the mold body, respectively, a submount molded inside the mold body and having an inclined surface on the lower portion, an edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to the outside.

The submount may further include a metal electrode extending from the inclined surface to the upper surface, and the edge-type light-emitting laser diode may have an electrode terminal connected to the metal electrode.

The O-SIP according to an embodiment of the present invention may include a driver IC unit molded inside the mold body to expose a bonding pad on the second surface and driving the edge-type light-emitting laser diode, and a heat dissipation metal structure having an upper surface in surface contact with a lower surface of the driver IC and a lower surface exposed to the second surface.

In addition, the O-SIP according to an embodiment of the present invention may include a plurality of conductive through mold vias (TMVs) through which one end is connected to a connection wiring of the redistribution layer and the other end passes through the mold body and is exposed to the second surface, a plurality of external connection terminals connected to the other ends of the plurality of conductive TMVs exposed on the second surface and arranged on the second surface.

The O-SIP according to another embodiment of the present invention may include a mold body having a first surface and a second surface which are flat on an upper portion and a lower portion of the mold body, respectively, a submount molded inside the mold body and having a side surface having an inclined surface, an edge-type light-emitting laser diode molded inside the mold body and mounted on the inclined surface of the submount to emit an optical signal to the first surface, and a redistribution layer formed on the second surface of the mold body and connected to a plurality of external connection terminals to electrically connect the edge-type light-emitting laser diode to the outside.

According to another aspect of the present invention, there is provided an optical module an optical system-in-package (O-SIP) having an edge-type light-emitting laser diode emitting an optical signal, and a planar light circuit (PLC) provided with a grating coupler mounted on a first surface of the O-SIP and placed in a position opposite to the edge-type light-emitting laser diode to receive an optical signal emitted from the edge-type light-emitting laser diode, wherein the O-SIP includes a mold body having the first surface and a second surface which are flat on an upper portion and a lower portion of the mold body, respectively, a submount molded inside the mold body and having an inclined surface on the lower portion, an edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to the outside.

When the optical signal emitted from the edge-type light-emitting laser diode is incident on the grating coupler of the PLC, the inclined surface of the submount may have an inclination angle of 82 degrees.

In addition, the PLC may include a flat body made of silicon photonics, a grating

coupler arranged inside the flat body facing the edge-type light-emitting laser diode to receive the light emitted from the edge-type light-emitting laser diode, a waveguide arranged inside the flat body and having one end connected to the grating coupler.

In addition, according to another aspect of the present invention, there is provided an optical module including an optical system-in-package (O-SIP) having an edge-type light-emitting laser diode emitting an optical signal, a printed circuit board (PCB) having a lower surface on which the O-SIP is mounted, and having a light passage window forming an optical path when an optical signal is generated in a vertical direction from a light-emitting unit at a portion corresponding to the light-emitting unit of the edge-type light-emitting laser diode, and a planar light circuit (PLC) provided with a grating coupler mounted on an upper surface of the O-SIP and placed in a position opposite to the edge-type light-emitting laser diode to receive, through the light passage window, an optical signal emitted from the edge-type light-emitting laser diode.

According to an embodiment of the present invention, the optical module may further include a micro-lens integrally formed on an upper surface of the O-SIP so as to focus the optical signal emitted from the edge-type light-emitting laser diode.

According to another aspect of the present invention, there is provided an optical module including an optical system-in-package (O-SIP) having an edge-type light-emitting laser diode emitting an optical signal, a printed circuit board (PCB) having a lower surface on which the O-SIP is mounted, and having a light passage window forming an optical path when an optical signal is generated in a vertical direction from a light-emitting unit at a portion corresponding to the light-emitting unit of the edge-type light-emitting laser diode, and a lens block mounted on the upper surface of the PCB and arranged at a position facing the edge-type light-emitting laser diode and having an inclined surface at which 90 degrees of bending is performed when the optical signal emitted from the edge-type light-emitting laser diode is incident through the light passage window.

According to an embodiment of the present invention, the optical module may include a micro lens arranged on a lower surface of the lens block facing the edge-type light-emitting laser diode to focus an optical signal generated from the edge-type light-emitting laser diode and incident thereon, a collimation lens for converting an optical signal emitted from an exit of the lens block into parallel light.

In addition, according to another aspect of the present invention, there is provided an optical module including an optical system-in-package (O-SIP) having an edge-type light-emitting laser diode emitting an optical signal, a guide block having an upper surface on which the O-SIP is mounted, and having a light passage window forming an optical path when an optical signal is generated in a vertical direction from a light-emitting unit at a portion corresponding to the light-emitting unit of the edge-type light-emitting laser diode, and a lens block mounted on the upper surface of the guide block and arranged at a position facing the edge-type light-emitting laser diode and having an inclined surface at which 90 degrees of bending is performed when the optical signal emitted from the edge-type light-emitting laser diode is incident through the light passage window.

The inclined surface may be provided at an oblique side of a regular triangular notch part formed on the upper surface of the body so as to convert the optical path into a right angle by total reflection using a difference in refractive index on the inclined surface.

According to another aspect of the present invention, there is provided an optical module including an optical system-in-package (O-SIP) having a plurality of edge-type light-emitting laser diodes emitting a plurality of channels of optical signals, a printed circuit board (PCB) having a lower surface on which the O-SIP is mounted and having a coupling groove at a portion corresponding to a light-emitting unit of the edge-type light-emitting laser diodes, an arrayed waveguide grating (AWG) provided with a front end portion having a reflective surface that is bent by 90 degrees, which is coupled when the optical signal emitted from the light-emitting unit is incident on the coupling groove, and performing wavelength division multiplexing (WDM) on the optical signals of the plurality of channels to transmit the same to an optical fiber, wherein the O-SIP includes a mold body having the first surface and a second surface which are flat on an upper portion and a lower portion of the mold body, respectively, a submount molded inside the mold body and having an inclined surface on the lower portion, an edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to the outside.

According to another aspect of the present invention, there is provided an optical module including an optical system-in-package (O-SIP) having a plurality of edge-type light-emitting laser diodes emitting a plurality of channels of optical signals, and an arrayed waveguide grating (AWG) which is mounted on the upper surface of the O-SIP, and provided with a front end portion having a reflective surface that is bent at 90 degrees, which is coupled when optical signals of a plurality of channels emitted from a light-emitting unit are incident on a portion corresponding to the light-emitting unit of the edge-type light-emitting laser diode, and performing wavelength division multiplexing (WDM) on optical signals of the plurality of channels to transmit same to an optical fiber, wherein the O-SIP includes a mold body having the first surface and a second surface which are flat on an upper portion and a lower portion of the mold body, respectively, a submount molded inside the mold body and having an inclined surface on the lower portion, the edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to the outside.

According to another aspect of the present invention, there is provided an optical transceiver including an optical system-in-package (O-SIP) having an edge-type light-emitting laser diode emitting an optical signal, a printed circuit board (PCB) having a lower surface on which the O-SIP is mounted, and having a light passage window forming an optical path when an optical signal is generated in a vertical direction from a light-emitting unit at a portion corresponding to the light-emitting unit of the edge-type light-emitting laser diode, a Lucent connector (LC) receptacle accommodating the PCB in a rear end accommodation space in which the O-SIP is mounted and having an optical fiber coupled to a front end portion thereof, wherein the O-SIP includes a mold body having the first surface and a second surface which are flat on an upper portion and a lower portion of the mold body, respectively, a submount molded inside the mold body and having an inclined surface on the lower portion, the edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to the outside.

The LC receptacle includes a body having an accommodation space for accommodating an optical module including an optical system-in-package (O-SIP) and a printed circuit board (PCB) at a rear end portion thereof, wherein a cylindrical coupling protrusion having an optical fiber coupling groove to which an optical fiber is coupled to a central portion protrudes from a front end portion thereof, and an optical lens integrally formed with the body in front of the accommodation space.

According to an embodiment of the present invention, the optical transceiver may further include an optical fiber holder having a coupling groove into which the cylindrical coupling protrusion is inserted and coupled to the rear end portion, and in which the optical fiber is supported on the central portion.

According to an aspect of the present invention, there is provided an optical transceiver including an optical system-in-package (O-SIP) having an edge-type light-emitting laser diode emitting an optical signal, a printed circuit board (PCB) having a lower surface on which the O-SIP is mounted, and having a light passage window forming an optical path when an optical signal is generated in a vertical direction from a light-emitting unit at a portion corresponding to the light-emitting unit of the edge-type light-emitting laser diode, and a Lucent connector (LC) receptacle having a rear end portion coupled to the PCB and an optical fiber coupled to a front end portion thereof, wherein the O-SIP includes a mold body having the first surface and a second surface which are flat on an upper portion and a lower portion of the mold body, respectively, a submount molded inside the mold body and having an inclined surface on the lower portion, the edge-type light-emitting laser diode molded inside the mold body and mounted on the inclined surface of the submount to emit an optical signal to the first surface, and a redistribution layer formed on the first surface of the mold body and connected to a plurality of external connection terminals to electrically connect the edge-type light-emitting laser diode to the outside.

To solve the assembly difficulty even when using passive alignment, according to this invention, there is provided a method of automating optical alignment in all directions of x, y, and z for single-mode edge-type light-emitting devices capable of long-distance transmission and AWG with single-mode waveguides for WDM transmission.

In addition, according to this invention, there is provided a method of vertically changing, to an optical system-in-package (O-SIP), an optical path emitted to a side surface (edge surface) of a chip of an edge-type light-emitting laser diode by using a submount without a separate optical component.

Furthermore, according to the present invention, there is provided an optical system-in-package (O-SIP) including an edge-type light-emitting laser diode and a driver IC in a package, and an optical module and an optical transceiver using the same. The O-SIP may include an optical engine module.

In particular, according to the present invention, in order to efficiently use a grating coupler of a silicon photonics forming a PLC chip, there is provided a method in which an edge-type light-emitting laser diode is erected and packaged in a semiconductor package using a submount. In this case, the structure and process of a general edge-type light-emitting laser diode may be used without changing.

In addition, to efficiently connect electrical connections between laser diodes, electronic driving devices (i.e., electronic ICs including driver ICs), and silicon photonics, laser diodes and electronic driving devices are packaged in a semiconductor package method in a FOWLP, and silicon photonics chips are stacked and electrically connected with each other on the FOWLP to minimize the length of wiring lines without wire-bonding.

The edge-type light-emitting laser diode and the driver IC are molded in a package, and the surface of the IC having the terminal pad and the light-emitting unit faces the redistribution layer. A redistribution layer is positioned on the mold body, and an external connection terminal is positioned on the rear surface of the redistribution layer or the mold body. A micro-lens, an optical system, a metasurface, or a layer having various patterns may be manufactured at a wafer level through an additional micro electro mechanical system (MEMS) or an imprint process on the redistribution layer.

In the related art, glass has been used as a lens to refract light to sharpen an image or to amplify the image. However, a metasurface serving as a metalens may have a structure such as a nano-sized column or pin, thereby concentrating light without image distortion.

When packaging is performed in the above-described FOWLP form, for example, when a surface mount technology (SMT) is applied to a main PCB in which an optical transceiver is embedded, the light emitting unit may be blocked due to the main PCB. To solve this problem, according to the present invention, it is possible to solve the problem by manufacturing a light entrance/exit part by making a through hole or using a transparent material in the main PCB. Thereafter, optical components such as necessary lenses and optical fibers may be assembled on the main PCB.

Furthermore, in the present invention, metal structures for heat dissipation may be arranged on the lower portions of the driver IC which are molded for heat dissipation of the driver IC. The surfaces of the metal structures are opened to expose the metal structures on the opposite surface of the package facing the redistribution layer of the FOWLP, and the exposed surfaces of the metal structures are connected to heat dissipation structures such as a heat sink or a thermal interface material (TIM) to form a heat dissipation path.

In addition, in order to electrically connect the lower portions of the driver IC, the metal structures may be connected to the redistribution layer located on the upper surface of the FOWLP. In this case, a metal may be deposited on the entire lower surface of the FOWLP at a wafer level to form a metal connection layer, and then the metal structure and the RDL of the FOWLP may be connected through the conductive via or the metal structures may be electrically connected therebetween by the metal connection layer.

According to the present invention, provided is an optical system-in-package (O-SIP) in which an edge-type light-emitting laser diode and a driver IC are located inside a package formed in a System-in-package (SIP) form without using a separate substrate, and an optical path to the outside of the edge-type light-emitting laser diode and the SIP is formed. The O-SIP of the present invention enables smaller and inexpensive optical transceivers as the substrate usage is excluded.

In the present invention, a slim O-SIP may be implemented by packaging an edge-type light-emitting laser diode and a driver IC by using a fan-out technology of pulling out input/output (I/O) terminals thereby increasing the I/O terminals, that is, a fan-out wafer level package (FOWLP) technology, while the edge-type light-emitting laser diode and the driver IC are integrated, without wire-bonding, by using a flip chip package technology, and simultaneously, while the devices are integrated without using a substrate.

In order to fix a chip (die) without using a substrate such as a PCB, the O-SIP, which is a kind of SIP technology, may miniaturize and slim at a level of 1/16 or so compared to a conventional package by packaging using an encapsulation material such as an epoxy mold compound (EMC) and reduce costs.

The optical module obtained by mounting the O-SIP according to the present invention on the main board (that is, the main PCB) or the module board (that is, the module PCB) may not only form a slim structure but also perform heat dissipation through a heat sink or a main body housing made of a metal through a dissipation metal structure attached to the rear surface of the O-SIP instead of the main board (that is, the main PCB), thereby preventing performance degradation.

### Advantageous Effects

As described above, the present invention provides a method of vertically changing the optical path of light emitted to the side surface (the edge surface) of the chip through packaging using submounts of edge-type light-emitting laser diodes without separate optical components.

In addition, in the semiconductor package according to the present invention, it is possible to reduce the performance of parts, the cost of assembly, and the minimization of the size of parts.

In the present invention, when an optical/electrical package is performed using a long-distance or high-power laser diode, that is, an edge-type light-emitting laser diode, a structure in which an optical coupling may be performed well with an optical component or an optical fiber having a silicon photonics chip or an optical function may be designed, and performance improvement and low power may be implemented by copackaging an edge-type light-emitting laser diode and a driver IC.

When optical coupling is performed using a silicon photonics chip, a grating coupler may be mainly used. In this case, light should be incident on the surface of the silicon photonics chip in a direction substantially perpendicular to the surface of the silicon photonics chip (or between 80 and 90 degrees). In particular, in the case that light emitted from the edge-type light-emitting laser diode is received using the grating coupler, the optical coupling effect may be maximized when incident with an inclination angle of 8 degrees with respect to the vertical axis.

However, in the case of a single mode laser diode, since light is emitted in a horizontal direction, that is, in an edge direction of the surface of a chip, a lens and a mirror should be further used to change the direction of light, which increases the complexity and cost of the assembly.

In order to solve the above problem, the present invention provides a method of erecting and packaging an edge-type light-emitting laser diode in a semiconductor package in order to efficiently use a grating coupler of silicon photonics. As a result, the structure and manufacturing process of a general edge-type light-emitting laser diode may be used without changing.

In addition, in order to efficiently perform electrical connection between the edge-type light-emitting laser diode, the driver IC, and the silicon photonics (SiPh), the laser diode and the driver IC are packaged in a FOWLP in a semiconductor package manner, and then the silicon photonics chip is stacked on the redistribution layer on the upper portion of the mold body of the FOWLP and electrically connected using the redistribution layer, thereby minimizing the length of the wiring line without wire bonding.

In addition, a driving chip should be connected for the electrical operation of the silicon photonics chip, and the external driving chip should have a very short wiring distance to enable excellent performance without signal loss.

Even though a silicon photonics chip is not used, it is often necessary to connect an edge-type light-emitting laser diode with an optical component/optical fiber. Likewise, even in this case, complex optical systems such as lenses are often required, and this invention provides a packaging method that easily and accurately implements integration between these parts.

According to the present invention, a product showing superior heat dissipation performance may be manufactured than an optical product through a conventional chip on-board (CoB) method and Fan-out Efficient Wafer Level Packaging (FOWLP) method. In addition, in the case of using the package structure of this invention, an optical module with the minimum thickness may be manufactured for each application as described in the following examples.

### BRIEF DESCRIPTION OF THE DRAWINGS

FIG. 1 is a cross-sectional view of an optical system-in-package (O-SIP) in which an edge-type light-emitting laser diode and a driver integrated circuit (IC) are packaged by a fan-out wafer level package (FOWLP) method and a planar light circuit (PLC) chip is assembled on a redistribution layer according to a first embodiment of the present invention.

FIG. 2 is a plan view of the O-SIP shown in FIG. 1.

FIG. 3A to FIG. 3G are process cross-sectional views showing a manufacturing process of manufacturing the O-SIP shown in FIG. 1 using a FOWLP method, respectively.

FIG. 4 is a cross-sectional view of an optical system-in-package (O-SIP) showing a package method when an electrode of a laser diode (LD) is arranged above and below a chip according to a second embodiment of the present invention.

FIG. 5 is a cross-sectional view of an optical system-in-package (O-SIP) showing a package method in which an external connection terminal is formed on a redistribution layer according to a third embodiment of the present invention.

FIG. 6 is a cross-sectional view illustrating an optical module according to a fourth embodiment of the present invention in which a PCB having a light passage window and a PLC are coupled to the O-SIP according to the third embodiment shown in FIG. 5.

FIG. 7 is a cross-sectional view illustrating an optical module according to a fifth embodiment of the present invention in which a PCB having a light passage window and a lens block are coupled to the O-SIP according to the third embodiment shown in FIG. 5.

FIGS. 8A and 8B are a schematic cross-sectional view showing the optical module according to the fifth embodiment of the present invention, and a cross-sectional view showing an optical transceiver manufactured using the optical module according to the fifth embodiment, respectively.

FIG. 9 is a cross-sectional view illustrating an optical module in which the lens block is coupled to the O-SIP according to the third embodiment shown in FIG. 5 according to a sixth embodiment of the present invention.

FIG. 10 is a cross-sectional view illustrating an optical module according to a seventh embodiment of the present invention in which a PCB and an AWG are coupled to an O-SIP according to the third embodiment shown in FIG. 5.

FIG. 11 is a cross-sectional view illustrating an optical module according to an eighth embodiment of the present invention in which an AWG is coupled instead of a PLC to the optical module according to the first embodiment of the present invention.

FIG. 12 is a cross-sectional view illustrating a ninth embodiment in which the light-emitting direction of the edge-type light-emitting laser diode is set in an opposite direction in the O-SIP according to the third embodiment shown in FIG. 5.

FIGS. 13A and 13B are cross-sectional views illustrating an optical transceiver in which an optical module to which an O-SIP according to the present invention is applied is connected to an optical fiber using an LC receptor (LC receptacle), in which FIG. 13A is an example of an LC receptacle made of a plastic material, and FIG. 13B is an embodiment employing an LC receptacle made of a metal material.

### BEST MODE FOR CARRYING OUT THE INVENTION

Hereinafter, embodiments of the present invention will be described in detail with reference to the accompanying drawings.

The sizes and shapes of the components shown in the drawings may be exaggerated for clarity and convenience. In addition, terms defined in consideration of the configuration and operation of the present invention may vary depending on the intention or custom of the user, the operator, and the like. Definitions of these terms should be based on the content of this specification.

The present invention relates to an optical system-in-package provided in an optical transceiver or the like, and the optical system-in-package may be mounted on a main PCB to constitute an optical module, and the optical module may be embedded in an optical transceiver.

The main PCB may include a Laser Diode Driver (LDD) and a Clock Data Recovery (CDR) for a Transmitter Optical Sub-Assembly (TOSA), a Transimpedance Amplifier (TIA)/Limiting Amplifier (LA) for a Receiver Optical Sub Assembly (ROSA), and a Micro Controller Unit (MCU) for performing overall transmission and reception control of an optical transceiver, which are mounted on the main PCB.

The main PCB may include an analog-to-digital converter (ADC) and a digital-to-analog converter (DAC), to perform signal processing in a digital signal processing method by a microcontroller unit (MCU) and a field programmable gate array (FPGA), and may include a digital signal processor (DSP) and a driver to drive a TOSA and a ROSA. In addition, the main PCB may be configured in various ways.

The present invention provides a structure of implementing an optical system-in-package (O-SIP) for generating an optical signal, in which an edge-type light-emitting laser diode and a driver IC for driving or interfacing the edge-type light-emitting laser diode are molded in a mold body having a first surface and a second surface which are flat. The O-SIP may include an optical engine module.

When describing an embodiment of the present invention, the O-SIP and the FOWLP may be used in the same meaning.

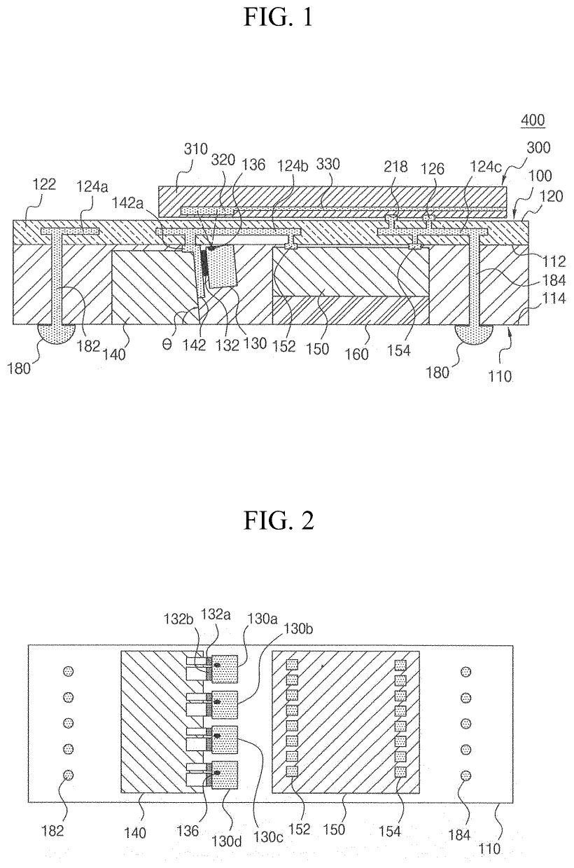

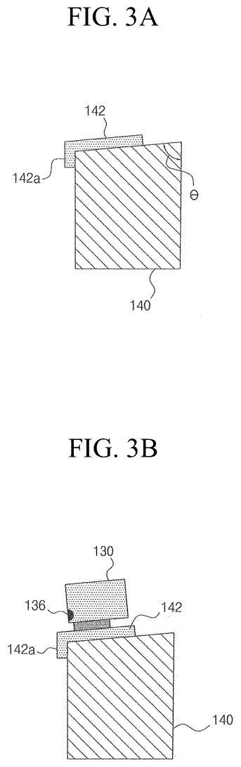

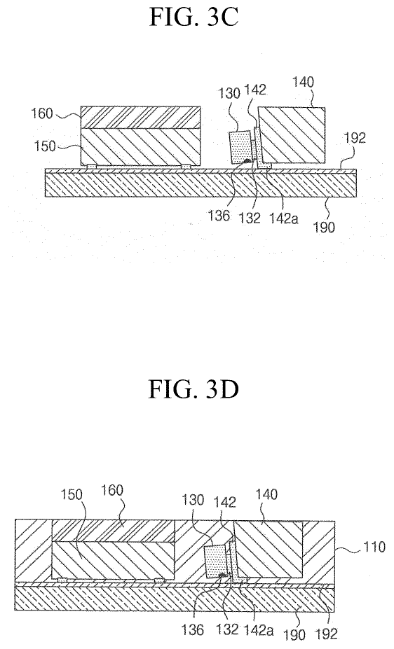

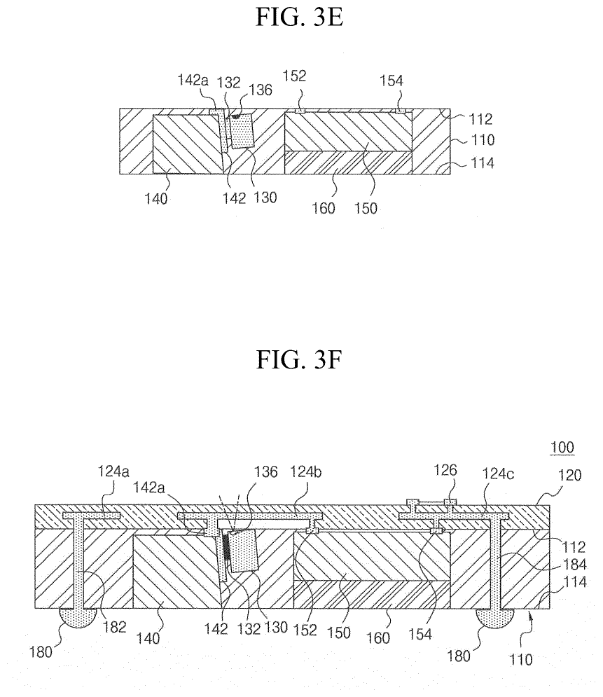

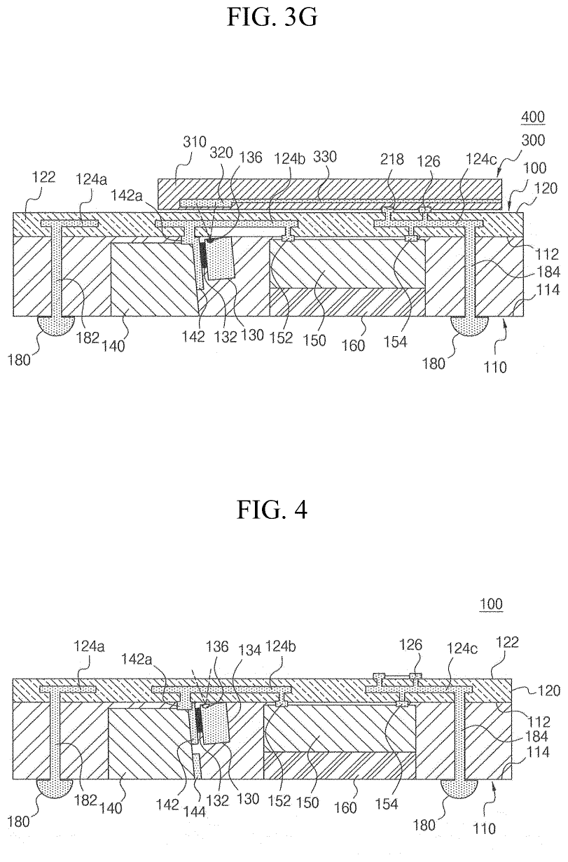

FIG. 1 is a cross-sectional view of an optical system-in-package (O-SIP) in which an edge-type light-emitting laser diode and a driver integrated circuit (IC) are packaged by a fan-out wafer level package (FOWLP) method and a planar light circuit (PLC) chip is assembled on a redistribution layer according to a first embodiment of the present invention. FIG. 2 is a plan view of the O-SIP shown in FIG. 1. FIG. 3A to FIG. 3G are process cross-sectional views showing a manufacturing process of manufacturing the O-SIP shown in FIG. 1 using a FOWLP method, respectively.

Referring to FIG. 1, an example in which an O-SIP is implemented using a FOWLP method using a via according to a first embodiment of the present invention will be described.

In the O-SIP 100 according to the first embodiment of the present invention, an edge-type light-emitting laser diode 130 and a driver IC 150 are packaged in a Fan-out Wafer Level Package (FOWLP) method inside a mold body 110 made of an epoxy mold compound (EMC), and a redistribution layer (RDL) 120 is arranged on a first surface 112 of the mold body 110.

The mold body 110 has a first surface 112 and a second surface 114 having flat upper and lower portions, respectively. In this case, the light of the edge-type light-emitting laser diode 130 is emitted to the first surface 112, and a plurality of external connection terminals 180 for connection with the outside are arranged on the second surface 114. In this case, as shown in FIG. 2, the external connection terminals 180 may be arranged in a fan-out form.

A planar light circuit (PLC) 300 chip is assembled on the redistribution layer 120.

In the mold body 110, a plurality of conductive through mold vias (TMVs) 182 and 184 are arranged to penetrate from the first surface 112 to the second surface 114. External connection terminals 180 made of, for example, solder balls are formed on the rear surface of the mold body 110, that is, the second surface 114 of the mold body 110, and are connected to connection wirings 124a and 124c of the redistribution layer 120 through the conductive TMVs 182 and 184.

Further, an edge-type light-emitting laser diode 130 is arranged at one side of the mold body 110 as a light-emitting element emitting light in an edge direction of a chip capable of long distance transmission, and a driver IC 150 for driving the edge-type light-emitting laser diode 130 is arranged on the other side of the mold body 110.

Moreover, the O-SIP 100 according to the first embodiment of the present invention may include an individual IC and an integrated IC that perform I2C communication, digital signal processing (DSP), clock data recovery (CDR), equalizer, and transimpedance amplifier (TIA) along with the driver IC 150, and may further include devices having various functions such as memory, logic, and analog driver.

The O-SIP 100 according to the first embodiment of the present invention is an embodiment in which the edge-type light-emitting laser diode 130, driver IC 150, and planar light circuit (PLC) 300 chips are packaged and assembled by a fan-out wafer level package (FOWLP) method, which is a type of advanced semiconductor package method.

In the present invention, the edge-type light-emitting laser diode 130 is vertically erected and molded inside the mold body 110 of the FOWLP as a light-emitting element emitting light in an edge direction of a chip capable of long-range transmission, and a submount 140 is used for this purpose.

In the present invention, the PLC 300 serves as an optical integrated circuit board and may use a silicon photonics chip, and when optical coupling is performed, the grating coupler 320 is mainly used. In this case, light should be incident on the surface of the silicon photonics chip in a substantially vertical direction (or between 80 and 90 degrees in inclination angle (θ) from the bottom surface of the mold body 110). The laser light emitted from the edge-type light-emitting laser diode 130 has strong straightness and may be reflected from the grating coupler 320, and in order to reduce such reflection and increase the optical coupling effect, it is preferable to set the incident angle of light to between 80 and 90 degrees.

To this end, the side surface of the submount 140 in which the edge-type light-emitting laser diode 130 is installed is required to have an inclination angle θ between 80 and 90 degrees, preferably 82 degrees.

In the sub-mount 140, continuous metal patterns 142 and 142a are arranged along the upper surface from the side surface of the submount 140 to be connected to the edge-type light-emitting laser diode 130 and a connection wiring 124b of the redistribution layer 120.

In this case, the electrode terminals 132a and 132b of the edge-type light-emitting laser diode 130 are connected to the side metal pattern 142, and the connection wiring 124b of the redistribution layer 120 is connected to the upper metal pattern 142a. As a result, the edge-type light-emitting laser diode 130 may be connected to the connection wiring 124b of the redistribution layer 120 through the metal patterns 142 and 142a.

In this case, the electrical connection between the edge-type light-emitting laser diode 130 and the submount 140 may be connected in various ways, such as eutectic bonding, soldering, and silver paste curing.

In the O-SIP 100 according to the present invention, the edge-type light-emitting laser diode 130 installed in the submount 140 and the driver IC 150, which is an electrical element, are molded in the mold body 110, the electrode terminals 132 a and 132 b of the edge-type light-emitting laser diode 130 are connected to the redistribution layer 120 through the metal patterns 142 and 142a, and the terminal pads 152 and 154 of the driver IC 150 are connected through the redistribution layer 120 of the mold body 110.

The redistribution layer 120 of the O-SIP 100 is arranged on the first surface 112 of the mold body 110 so as to be in charge of the connection between elements inside the mold body 110, the connection with the external connection terminal 180 made of a ball grid array (BGA) of the O-SIP 100, and the electrical connection with the chip of the PLC 300 arranged outside the O-SIP 100.

The PLC 300 is arranged on the redistribution layer 120 of the mold body 110, and aligns the positions of the grating coupler 320 receiving light from the edge-type light-emitting laser diode 130 and the light-emitting unit 136 of the edge-type light-emitting laser diode 130. In addition, the terminal pad 218 of the PLC 300 and the connection pad 126 on the redistribution layer 120 are electrically connected to each other so that the driver IC 150 may drive the PLC 300 through the connection wiring 124b.

The PLC 300 may serve as an integrated circuit board for performing various functions such as multiplexer (MUX), demultiplexer (DEMUX), modulation, beam steering, beam splitter, wavelength division multiplexing (WDM), and the like because the body 310 has a waveguide 330 formed on a flat chip. In addition, the PLC 300 may be implemented to include various optical elements such as an optical filter, a free space MUX/DEMUX, and the like.

When optical coupling is performed using a silicon photonics chip as the PLC 300, the grating coupler 320 is mainly arranged at a position opposite to the edge-type light-emitting laser diode 130.

The PLC 300 may use a chip using silicon photonics, a chip using silica, SiN, or the like. FIG. 2 is a plan view of the O-SIP shown in FIG. 1.

Referring to FIG. 2, the O-SIP 100 according to the first embodiment of the present invention includes, for example, four or one submount 140 on which edge-type light-emitting laser diodes 130a to 130d are mounted to be vertically erected and arranged side by side in a mold body 110 to implement four channels, and a driver IC 150 in which four drivers for driving the edge-type light-emitting laser diodes 130a to 130d are integrated and embedded to be spaced apart from the four edge-type light-emitting laser diodes 130a to 130d.

A plurality of terminal pads 152 and 154 are arranged on both sides of the driver IC 150, respectively. The plurality of terminal pads 152 and 154 are connected to connection wirings 124a to 124c of the redistribution layer 120.

In addition, the connection wirings 124a to 124c are connected to a plurality of external connection terminals 180 arranged on the second surface 114 of the mold body 110 through a plurality of conductive TMVs 182 and 184 formed at both ends of the rear end of the mold body 110.

Hereinafter, a manufacturing process of manufacturing the O-SIP shown in FIG. 1 using the FOWLP method will be described with reference to FIGS. 3A to 3G.

First, as shown in FIG. 3A, a submount 140 is manufactured. For example, the submount 140 may be made of various materials such as silicon, SiN, aluminum oxide, a nickel-cobalt alloy (e.g., KOVAR™), and the like.

Metal is plated on the upper surface and the side surface of the submount 140 so that metal patterns 142 and 142a are continuously connected along the upper surface from the side surface. In this case, an angle is given to the upper surface of the submount 140 to which the edge-type light-emitting laser diode 130 is attached so that the laser beam may emit light by giving an angle of 0 to 10 degrees, preferably 8 degrees, from the vertical direction rather than from the vertical direction.

Subsequently, as shown in FIG. 3B, the edge-type light-emitting laser diode 130 is electrically connected to the prepared submount 140 in a flip form.

Then, as shown in FIG. 3C, the driver IC 150 and the metal pattern 142a of the submount 140 are placed on a prepared carrier 190 facing the floor. In this case, a double-sided adhesive tape 192 is laminated on the carrier 190 so that a chip that picks and places is fixed.

Furthermore, a heat dissipation metal structure 160 is attached to the upper surface of the driver IC 150 in advance.

Thereafter, as shown in FIG. 3D, the driver IC 150, the submount 140, and the edge-type light-emitting laser diode 130 are molded using a molding material. The mold may employ a P-Mold method or a C-Mold method, and an epoxy mold compound (EMC) may be used as the molding material.

In other words, EMC and epoxy resin may be used to mold the driver IC 150, submount 140, and edge-type light-emitting laser diode 130, and several cells may be molded at once at a wafer and panel level in a molding operation. After the molding material is cured, the upper surface is planarized by a chemical mechanical polishing (CMP) method until the surface of the metal structure 160 is exposed.

Then, when the carrier 190 and the double-sided adhesive tape 192 are removed from the molded form and turned over, the terminal pads 152 and 154 face upward as shown in FIG. 3E, and in this state, the process of forming the redistribution layer 120 as shown in FIG. 3F is performed.

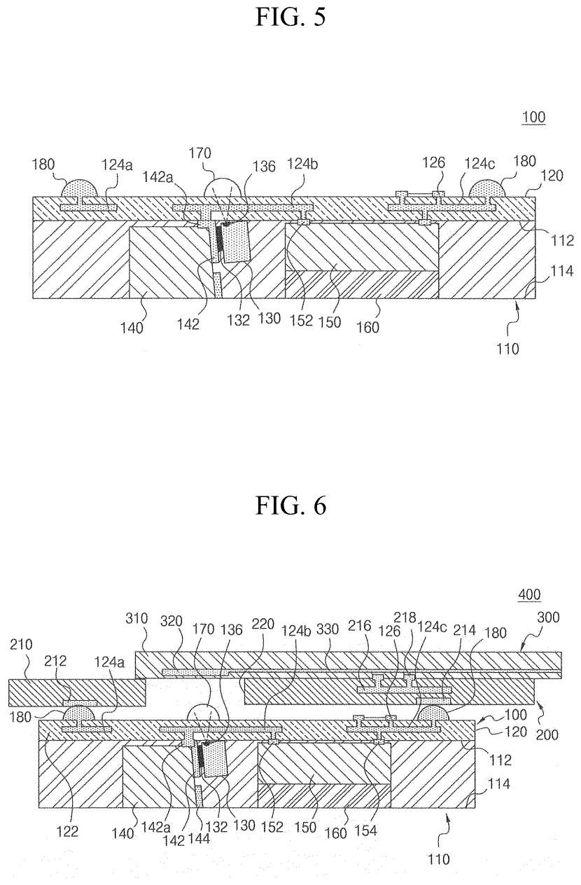

The redistribution layer 120 is formed on the first surface 112 of the mold body 110. The redistribution layer 120 may include an external connection terminal 180 formed on the second surface 114 of the mold body 110 through the TMVs 182 and 184 as in the second embodiment shown in FIG. 4, or an external connection terminal 180 may be arranged on the redistribution layer 120 as in the third embodiment shown in FIG. 5.

The case in which the chip of the PLC 300 is mounted on the redistribution layer 120 includes the external connection terminal 180 on the rear surface of the mold body 110, that is, the second surface 114, as in the second embodiment illustrated in FIG. 4. As shown in FIG. 6, when the chip of the PLC 300 is mounted on a main PCB 200 and the main PCB 200 is directly mounted on the redistribution layer 120, the external connection terminal 180 may be preferably arranged on the redistribution layer 120 as in the third embodiment illustrated in FIG. 5. As in the first and second embodiments, when the external connection terminal 180 is formed on the rear surface of the mold body 110, that is, the second surface 114, the O-SIP 100 may be mounted on the upper portion of the main PCB knob 200.

In order to form an insulating layer 122 for the redistribution layer 120, various materials such as polyimide, SiO₂, and epoxy-series may be used, and a photo-lithography process may be used to form a pattern of the connection wirings 124a to 124c. In this case, the material of the connection wiring 124a to 124c itself may act as a developable photoresist (PR), and the wiring layer may be etched after additional PR coating. The metal layer may be deposited after the formation of the insulating layer 122, and the metal used to form the connection wirings 124a to 124c of the redistribution layer 120 may include various metal materials such as Cu, Al, Au, Ag, or a compound thereof. The external connection terminal 180 formed on the redistribution layer 120 may be manufactured by directly exposing a metal surface of the redistribution layer 120 to the outside, such as a land grid array (LGA) type, or mounting solder balls on an upper portion of the mold body 110, such as a ball grid array (BGA) type.

Thereafter, as shown in FIG. 3G, when the chip of the external PLC 300 is fixed on the FOWLP, an optical module 400 is completed.

Meanwhile, in the present disclosure, the metal structure 160 may be formed under the driver IC 150 for additional heat dissipation. A size of the metal structure 160 may be larger or smaller than a size of the driver IC 150. In the method of forming the metal structure 160, after the metal structure 160 is attached to the lower portion of the driver IC 150, the FOWLP process may be performed in a state in which the metal structure 160 in surface contact with the driver IC 150 is attached.

In this case, an adhesive may be used to attach the driver IC 150 and the metal structure 160, and the adhesive may be silver epoxy or epoxy, EMC, or carbon nanotube (CNT) compound. For the best heat dissipation performance and electrical conductivity, a conductive material such as silver epoxy may be used. In the present invention, the metal structure 160 may be used to apply an electric signal to the lower surface of the mold body 110.

When connecting the edge-type light-emitting laser diode 130 mounted on the submount 140 with the driver IC 150 and the redistribution layer 120, a via-type conductive structure should be formed in the mold body 110. The via-type conductive structure may use a PCB including a conductive via, may be molded together with another edge-type light-emitting laser diode 130 and a driver IC fab 150 during a FOWLP process using a Cu piece, and may be electrically connected to a metal structure of a lower portion of the IC to be wired after the upper and lower metals are exposed. In this case, a metal may be deposited at a wafer level to be connected without a pattern, or another redistribution layer 120 may be formed on an opposite surface of the redistribution layer 120 of the FOWLP wafer to connect the redistribution layers 120 on both surfaces to each other.

FIG. 4 is a cross-sectional view of an optical system-in-package (O-SIP) showing a package method when an electrode of an edge-type light-emitting laser diode 130 is arranged above and below a chip according to a second embodiment of the present invention.

Referring to FIG. 4, an optical system-in-package (O-SIP) 100 according to a second embodiment of the present invention illustrates a package method when an electrode of an edge light-emitting laser diode 130 is located above and below a chip. In this case, the metal pattern 144 of the submount 140 and the opposite electrode of the edge-type light-emitting laser diode 130 may be connected by wire-bonding using the bonding wire 134 after the operation of manufacturing the submount 140 (FIG. 3B). Thereafter, the packaging process is performed in the same manner.

FIG. 5 illustrates an optical system-in-package (O-SIP) showing a package method in which an external connection terminal 180 is formed on a redistribution layer 120 according to a third embodiment of the present invention.

Referring to FIG. 5, the O-SIP 100 according to the third embodiment of the present invention has a structure in which both the external connection terminal 180 and the redistribution layer 120 are formed on the first surface 112 of the mold body 110 without using the through mold vias (TMVs) 182 and 184 penetrating the mold body 110.

The O-SIP 100 according to the third embodiment may be combined with the main PCB 200 to form the optical module 400, as shown in FIG. 6.

In this case, a position to which the main PCB 200 is fixed is different from that of the fourth embodiment shown in FIG. 6. In addition, an example in which a micro-lens 170 having a function of focusing light emitted from the edge-type light-emitting laser diode 130 is manufactured in the redistribution layer 120 on the mold body 110 to focus light emitted from the edge-type light-emitting laser diode 130 is additionally illustrated.

Since the optical path of light emitted from the O-SIP 100 is lengthened when the light passes through the main PCB 200, a part of the lens structure such as the micro-lens 170 is inserted after forming the light passage window 220 inside the main PCB 200 to prevent the spread of light by reducing the distance between the micro-lens 170 and the O-SIP 100.

FIG. 6 illustrates a fourth embodiment in which a main PCB having a light passage window and a PLC are combined with an O-SIP according to the third embodiment illustrated in FIG. 5.

Referring to FIG. 6, the optical module 400 according to the fourth embodiment shows an embodiment in which the PLC 300 is arranged on the main PCB 200 having the light passage window 220 after drilling a hole in the main PCB 200.

The package of the O-SIP 100 having the structure described above may be mounted on a lower portion of the main PCB 200 as shown in FIG. 6, and in this case, a surface mount technology (SMT) method may be used. After the O-SIP 100 is mounted under the main PCB 200, an optical path entering and exiting the light-emitting unit 136 of the O-SIP 100 may be formed inside the main PCB 200.

In this case, an optical path is formed by penetrating the main PCB 200 or making a partial groove. A light passage window 220 may be formed by processing a through hole in the main PCB 200 to form an optical path, or a portion or an entire surface of the PCB may include a transparent material to form an optical path.

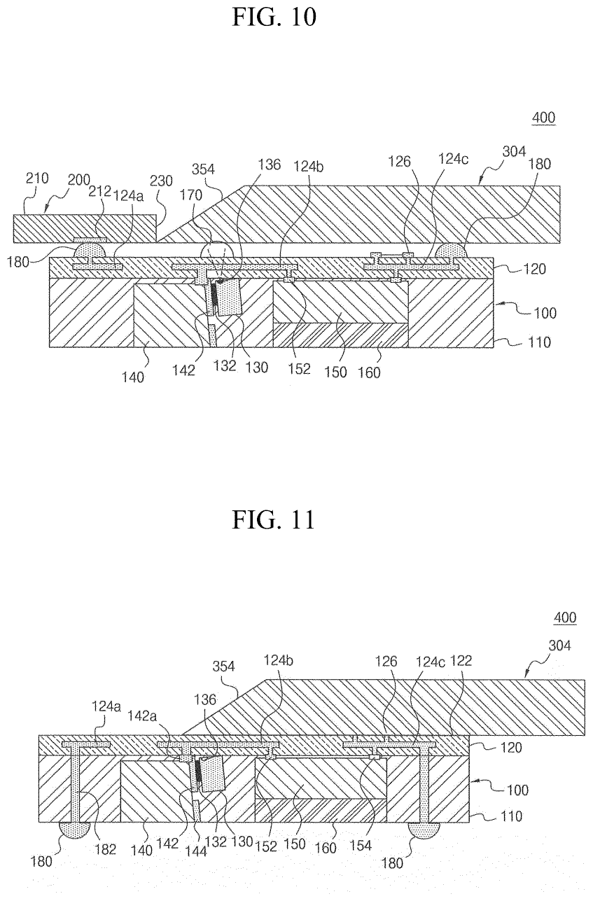

In addition, when there is a structure that may transmit an optical signal inside the main PCB 200 or to the surface of the main PCB 200, the optical signal may be transmitted (connected) to the optical structure on the main PCB 200 without penetrating the optical signal (see FIG. 10).

In this case, the main PCB 200 may include not only a multilayer printed circuit board (PCB) made of, for example, FR4, but also a connection wiring 216 formed inside the substrate using Si or glass and terminal pads 212, 214, and 218 connected to the connection wiring 216.

The PLC 300 mounted on the main PCB 200 may be electrically connected to the driver IC 150 through the connection wiring 124c of the redistribution layer 120, the external connection terminal 180, and the connection wiring 216 of the main PCB 200.

In the optical module 400 according to the fourth embodiment, an optical fiber may be matched to a front end of the PLC 300 through an adapter.

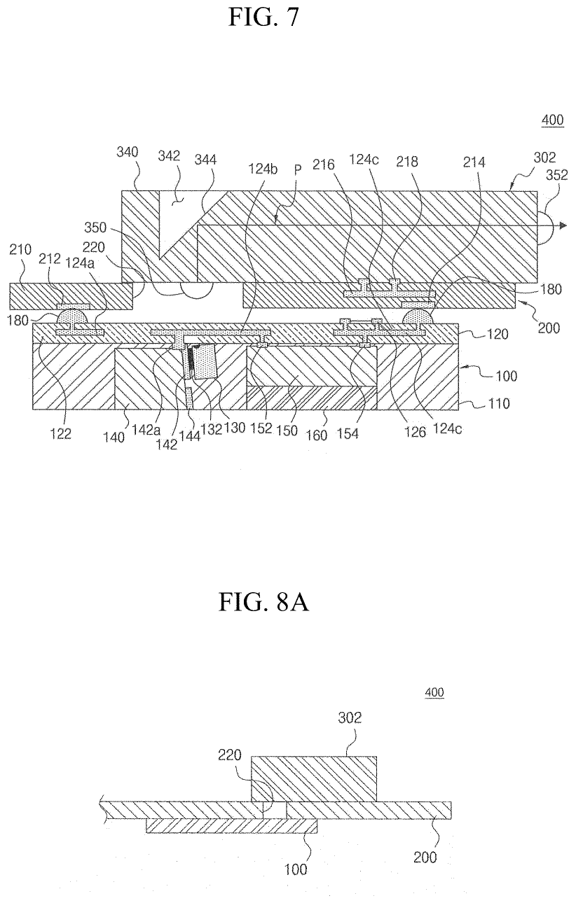

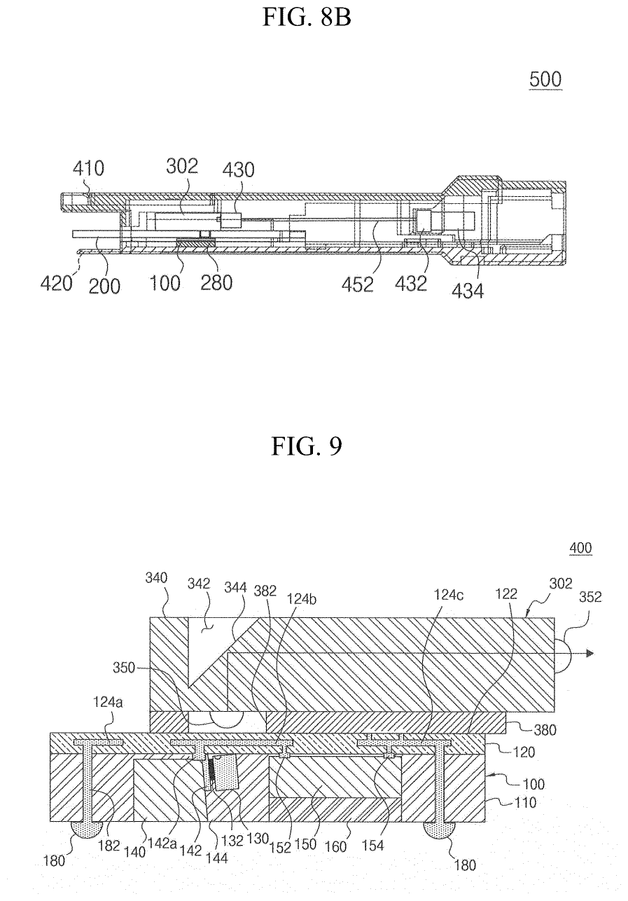

FIG. 7 is a cross-sectional view illustrating an optical module according to a fifth embodiment of the present invention in which a PCB having a light passage window and a lens block are coupled to the O-SIP according to the third embodiment shown in FIG. 5. FIGS. 8A and 8B are a schematic cross-sectional view showing the optical module according to the fifth embodiment of the present invention, and a cross-sectional view showing an optical transceiver manufactured using the optical module according to the fifth embodiment, respectively.

Referring to FIG. 7, in the optical module 400 according to the fifth embodiment of the present invention, the O-SIP 100 according to the third embodiment shown in FIG. 5 is mounted on the lower portion of the main PCB 200 having the light passage window 220, and a lens block 302 is coupled to the upper portion of the main PCB 200.

The difference between the optical module 400 according to the fifth embodiment and the optical module 400 according to the fourth embodiment of the present invention is present in a point of view that the lens block 302 is coupled to the upper portion of the main PCB 200 instead of the PLC 300, and the other parts are the same.

The description of the same parts between the optical module 400 according to the fifth embodiment and the optical module 400 according to the fourth embodiment will be omitted and only the different parts will be described.

The lens block 302 is an optical component for converting the optical path P by 90 degrees in the same direction as a housing when the optical module 400 is accommodated inside the housing of an optical transceiver, as described later, and when the light emitted from the O-SIP 100 passes through the light passage window 220 of the main PCB 200 and heads upward, an inclined surface 344 for bending the optical path P at a right angle in a horizontal direction with respect to the main PCB 200 is provided on the upper surface of a body 340 made of flat surfaces on both sides.

The body 340 of the lens block 302 may include plastic or glass, and a notch portion 342 having an equilateral triangle shape may be formed on the upper surface of the body 340 to convert the optical path P to a right angle by total reflection using a difference in refractive index on the inclined surface 344.

In this case, the hypotenuse of the equilateral triangular notch 342 forms a 45-degree slope, and the inclined surface 344 is set so that the vertical optical signal generated by the O-SIP 100 is located at a point where the horizontal direction intersects the main PCB 200.

A micro lens 350 for focusing light to concentrate light may be formed on the lower surface of the lens block 302 at a position where the vertical optical signal generated from the O-SIP 100 is incident on the inclined surface 344.

In addition, a collimation lens 352 may be formed at the exit of the lens block 302 to make the emitted light straight in parallel light without spreading.

In the optical module 400 constructed above according to the fifth embodiment of the present invention, as shown in FIG. 8A, an O-SIP 100 is mounted on the lower portion of the main PCB 200 with the light passage window 220, and the lens block 302 is coupled to the upper portion of the main PCB 200.

An optical transceiver 500 manufactured using the optical module 400 according to the fifth embodiment may be implemented as shown in FIG. 8B.

Referring to FIG. 8B, an optical transceiver 500 or an active optical cable (AOC) is manufactured by assembling the optical module 400 inside a housing consisting of an upper housing 410 and a lower housing 420. In this case, the rear end portion of the optical transceiver 500 is connected to a main body such as a one-side terminal, and a connector of an optical cable is coupled to the front end portion of the optical transceiver 500.

In this case, a thermal interface material (TIM) 280 may be inserted between a lower housing 420 made of metal of the optical transceiver for heat dissipation and the metal structure 160 for heat dissipation of the O-SIP 100 to perform heat dissipation.

The optical module 400, which is assembled inside the housing consisting of the upper housing 410 and the lower housing 420, has an optical fiber coupling holder (or a fiber block) 430 physically coupled to the front end of the lens block 302, and the optical fiber coupling holder 430 may be connected to an optical cable connector including an LC receptacle 432 through a pigtail fiber 452. In addition, a socket coupling part 434 to which a plug of an optical cable (not shown) is coupled protrudes from the front end of the LC receptacle 432.

Although the embodiments described above illustrate that the edge-type light-emitting laser diode 130 for long-distance transmission is mounted on the submount 140, vertical cavity surface emitting laser (VCSEL) may be used as a photonic IC molded in the package of the O-SIP 100. In this case, the O-SIP 100 may be used as an optical engine module for a transmitter TX of the optical transceiver 500 that connects short distances within 100 m to 300 m through a multi-mode optical fiber.

FIG. 9 is a cross-sectional view illustrating an optical module in which the lens block is coupled to the O-SIP according to the third embodiment shown in FIG. 5 according to a sixth embodiment of the present invention.

Referring to FIG. 9, the optical module 400 according to the sixth embodiment of the present invention has a structure in which a lens block 302 is coupled to an upper portion of the O-SIP 100 according to the third embodiment shown in FIG. 5.

The optical module 400 according to the sixth embodiment of the present invention differs from that of the fifth embodiment in that a guide block 380 with a light passage window 382 is installed instead of the main PCB 200 with a light pass window 220 in the fifth embodiment shown in FIG. 7, and the rest of the parts are the same.

The description of the same parts between the optical module 400 according to the sixth embodiment and the optical module 400 according to the fifth embodiment will be omitted and only the different parts will be described.

The lens block 302 used in the optical module 400 according to the sixth embodiment is an optical component for bending the optical path P by 90 degrees, and is provided with an inclined surface 344 for bending the optical path P at a right angle in a horizontal direction with respect to the main PCB 200, when the light emitted from the O-SIP 100 passes through the light passage window 220 of the main PCB 200 and heads upward.

The lens block 302 used in the optical module 400 according to the sixth embodiment is the same as in the fifth embodiment, and the 45-degree inclined surface 344 is set to be located at a point where the vertical optical signal generated by the O-SIP 100 intersects the main PCB 200 in the horizontal direction.

In addition, a micro-lens 350 for focusing light is formed on the lower surface of the lens block 302 to concentrate light, and a collimation lens 352 may be formed at the exit of the lens block 302 to make the emitted light straight in parallel light without spreading.

The guide block 380 inserted between the lens block 302 and the O-SIP 100 has a light passage window 382, and the micro-lens 350 protrudes from the light passage window 382. The guide block 380 serves to safely protect the micro-lens 350 while minimizing the distance between the micro-lens 350 and the O-SIP 100.

FIG. 10 is a cross-sectional view illustrating an optical module according to a seventh embodiment of the present invention in which a PCB and an AWG are coupled to an O-SIP according to the third embodiment shown in FIG. 5.

Referring to FIG. 10, an optical module 400 according to a seventh embodiment of the present invention has a structure in which an O-SIP 100 is mounted on a lower portion of a main PCB 200 having a coupling groove 230 formed on one side thereof, and a front end portion of an array waveguide grating (AWG) 304 is inserted into the coupling groove 230.

The optical module 400 according to the seventh embodiment has a slot-shaped coupling groove 230 on one side of the main PCB 200 to accommodate the front end of the AWG 304, and the O-SIP 100 is mounted on the lower surface of the main PCB 200 so that the light- emitting unit 136 of the edge-type light-emitting laser diode 130 matches the coupling groove 230.

In this case, an external connection terminal 180 made of a solder ball connected to the connection wiring 124a of the redistribution layer 120 is connected to the terminal pad 212 arranged under the main PCB 200.

The AWG 304 is a photonic IC of an optical transmission sub-assembly (TOSA) and serves to transmit, for example, four-channel optical signals generated from the edge-type light-emitting laser diode 130 to the optical fiber 452 by performing a wavelength division multiplexing (WDM) function.

The AWG 304 may include, for example, an optical multiplexer unit performing an optical multiplexing function, a plurality of input waveguides connected to a front end portion of the optical multiplexer unit to receive a plurality of optical signals incident from a plurality of light-emitting devices, and a single mode output waveguide connected to a rear end portion of the optical multiplexer unit to output one optical signal output after the plurality of optical signals have been multiplexed.

In this case, the AWG 304 is processed to have an end facing the edge-type light-emitting laser diode 130 processed into an angled inclined surface 354 so that four channels of optical signals generated from four light-emitting devices are bent vertically at the end of the AWG 304 so as to be incident through the four input waveguides of the AWG 304. A total reflection refraction occurs in the inclined surface 354 exposed in the air of the AWG 304.

Accordingly, the optical module 400 for optical transmission may realize a wavelength multiplexer (WDM MUX) of 25 Gbps per channel (that is, 25 Gbps×4 channels=100 Gbps). In addition, the optical module 400 for optical transmission may realize a wavelength multiplexer (WDM MUX) having 100 Gbps per channel (=10 Gbps×10 channels).

The optical module 400 according to the seventh embodiment may manufacture an optical transceiver 500 or an active optical cable (AOC) manufactured by assembling inside a housing consisting of the upper housing 410 and the lower housing 420 shown in FIG. 8B. In this case, the rear end portion of the optical transceiver 500 is connected to a main body such as a one-side terminal, and a connector of an optical cable is coupled to the front end portion of the optical transceiver 500.

FIG. 11 is a cross-sectional view illustrating an optical module according to an eighth embodiment of the present invention in which an AWG is coupled to the O-SIP according to the third embodiment.

Referring to FIG. 11, the optical module 400 according to the eighth embodiment of the present invention shows an example in which the AWG 304 is directly coupled instead of the PLC 300 in the O-SIP 100 according to the first embodiment without using the main PCB 200.

In the optical module 400 according to the eighth embodiment of the present invention, an end portion of the AWG 304 facing the edge-type light-emitting laser diode 130 of the O-SIP 100 is processed into an inclined surface 354 with an angle so that the four-channel optical signals generated from the four light-emitting devices are bent vertically at the end of the AWG 304 and incident through the four input waveguides of the AWG 304. A total reflection refraction occurs in the inclined surface 354 exposed in the air of the AWG 304.

In the optical module 400 according to the eighth embodiment of the present invention, an external connection terminal 180 made of a solder ball connected to the connection wiring 124a of the redistribution layer 120 is connected to the lower surface of the O-SIP 100.

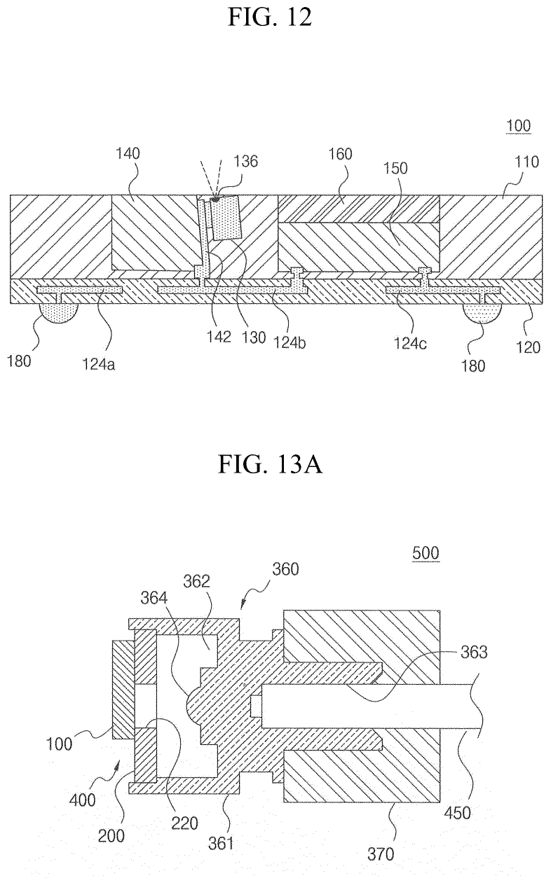

FIG. 12 is a cross-sectional view illustrating a ninth embodiment in which the light-emitting direction of the edge-type light-emitting laser diode is set in an opposite direction in the O-SIP according to the third embodiment shown in FIG. 5.

Referring to FIG. 12, the light-emitting direction of the edge-type light-emitting laser diode 130 in FIG. 12, is formed to be opposite to the light-emitting direction of the edge-type light-emitting laser diode 130 in FIG. 5. In the ninth embodiment, a redistribution layer 120 is arranged under the mold body 110, an external connection terminal 180 is formed in the redistribution layer 120, and a main PCB 200 may be mounted on the external connection terminal 180.

The package of the O-SIP 100 of the ninth embodiment has a structure capable of directing the divergence direction of light upward without using a conductive TMV 182 inside the mold body 110 while still placing the main PCB 200 on the bottom surface.

The package of the O-SIP 100 of the ninth embodiment may require a FOWLP to be processed in a face-up manner, and in this case, a metal structure 160 made of a Cu stud metal may be added onto the driver IC 150.

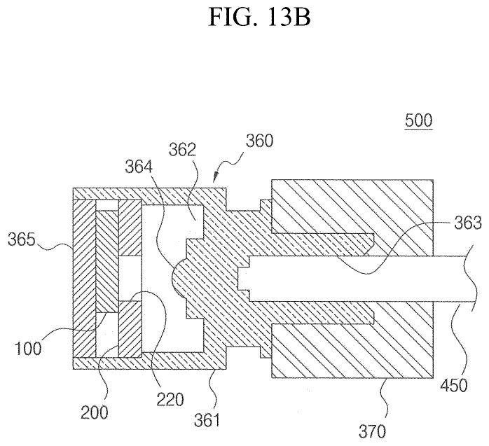

FIGS. 13A and 13B are cross-sectional views of optical transceivers that can be applied to 5G networks, respectively, showing the combined structure of an LC receptacle that couples an O-SIP to an optical fiber according to the present invention, in which FIG. 13A employs an LC receptacle made of plastic, and FIG. 13B employs an LC receptacle made of metal.

The optical transceiver 500 according to the present invention has a structure in which an optical module 400 to which the O-SIP 100 according to the first embodiment is applied is combined with an optical fiber 410 using an LC receptacle 360, and may be applied to a 5G network.

First, the O-SIP 100 according to the first embodiment is mounted on the main PCB 200 in which a through hole 220 is formed, and then assembled and fixed to the rear end portion of the LC receptacle 360.

A method of combining the optical module 400 in which the O-SIP 100 is mounted on the main PCB 200 with the LC receptacle 360 may be performed in one of the following two methods.

First, the LC receptacle 360 has an accommodation space 362 on the rear end side of the body 361 to accommodate an optical module 400, an optical lens 364 is integrally formed in front of the accommodation space 362, and a cylindrical coupling protrusion having an optical fiber coupling groove 363 to which the optical fiber 410 is coupled is protruded on the center portion of the front end side of the body 361.

An optical fiber holder 370 is detachably coupled to the cylindrical coupling protrusion, and an optical fiber holder 370 has a coupling groove to which the cylindrical coupling protrusion is inserted and coupled at the rear end portion thereof, and the optical fiber 410 is supported at the center of the optical fiber holder 370.

Accordingly, when the optical fiber holder 370 is assembled to the cylindrical coupling protrusion of the body 361, the front end portion of the optical fiber 410 is accommodated in the optical fiber coupling groove 363, and the optical axis alignment with the optical lens 364 may be achieved.

As illustrated in FIG. 13A, the method of combining the optical module 400 with the LC receptacle 360 may be performed by inserting and press-fitting the main PCB 200 of the optical module 400 into the accommodation space 362 to be fixed at the rear end portion of the LC receptacle 360.

The LC receptacle 360 shown in FIG. 13A includes plastic.

In this case, fixing the LC receptacle 360 to the main PCB 200 may allow the LC receptacle 360 to surround the main PCB 200 as shown in FIG. 13A, and the main PCB 200 may be manufactured to be larger than the LC receptacle 360 to attach the LC receptacle 360 on the main PCB 200. The light passing through the main PCB 200 may be concentrated toward the optical fiber 410 through the optical lens 364 in the LC receptacle 360.

For optical alignment, it is possible to use an active alignment method in which the LC receptacle 360 is fixed at a position where the optimal amount of light is obtained while measuring the amount of light of the optical fiber 410 after inserting the optical fiber 410 into the LC receptacle 360.

A thermoelectric cooler (TEC) for temperature control may be attached to the rear surface of the O-SIP 100. In this case, an operating temperature section of the O-SIP 100 may be extended. The TEC is a cooler that uses the Peltier effect to generate a heat flux between two material junction points and cools by transferring heat from one side of a device to the other while consuming electrical energy according to a direction of a current.

For example, when a VCSEL is used as a light-emitting device, the operating temperature is limited to 0° C. to 70° C., and if the TEC is attached and used, the operating temperature may be widened from −40° C. to 85° C. The use of the TEC may be equally applied to the structure of the O-SIP 100 described above. When the TEC is used, a thermistor for temperature measurement may be embedded in the O-SIP 100.

As shown in FIG. 13B, another method of combining the optical module 400 with the LC receptacle 360 is to insert both the O-SIP 100 and the main PCB 200 of the optical module 400 into the accommodation space 362 at the rear end of the LC receptacle 360, and press-fit the outer periphery of the main PCB 200, and assemble a sealing cover 365 at the rear end of the LC receptacle 360.

The LC receptacle 360 shown in FIG. 13B includes metal, and when the sealing cover 365 is assembled at the rear end of the LC receptacle 360, and then welding is performed, fixing and hermetic sealing is possible.

While the present invention has been particularly shown and described with reference to exemplary embodiments thereof, by way of illustration and example only, it is clearly understood that the present invention is not to be construed as limiting the present invention, and various changes and modifications may be made by those skilled in the art within the protective scope of the invention without departing off the spirit of the present invention.

### INDUSTRIAL APPLICABILITY

The present invention be applied to implement an optical module using an optical system-in-package (O-SIP), in which the O-SIP includes an edge-type light-emitting laser diode and a driver IC in the package, and a planar light circuit (PLC) is assembled directly or through a printed circuit board (PCB) on a redistribution layer (RDL).

Thus, the optical module may be used in various ways in the optical communication and optical sensor industries. For optical communication, communication between servers inside a data center, and optical transceivers for 5G and 6G communication networks may be used.

In addition, since miniaturization and integration are implemented in a package in the case of the present invention, the optical module may also be used for on-board optical communication and chip-to-chip optical communication.

Moreover, by implementing a silicon optical phase array (OPA), beam steering may be implemented on a chip, which may be used in LIDAR for vehicles.

1. An optical system-in-package (O-SIP) comprising:
a mold body having the first surface and a second surface which are flat on an upper portion and a lower portion of the mold body, respectively;
a submount molded inside the mold body and having a side surface having an inclined surface;
an edge-type light-emitting laser diode molded inside the mold body and mounted on the inclined surface of the submount to emit an optical signal to the first surface; and
a redistribution layer formed on the first surface or on the second surface of the mold body and connected to a plurality of external connection terminals to electrically connect the edge-type light-emitting laser diode to the outside.

2. The O-SIP of claim 1, wherein the submount further comprises a metal electrode extending from the inclined surface to the upper surface, and the edge-type light-emitting laser diode has an electrode terminal connected to the metal electrode.

3. The O-SIP of claim 1, further comprising:
a driver IC unit molded inside the mold body to expose a bonding pad on the first surface and driving the edge-type light-emitting laser diode; and
a heat dissipation metal structure having an upper surface in surface contact with a lower surface of the driver IC and a lower surface exposed to the second surface.

4. The O-SIP of claim 1, further comprising:
a plurality of conductive through mold vias (TMVs) through which one end is connected to a connection wiring of the redistribution layer and the other end passes through the mold body and is exposed to the second surface, and
a plurality of external connection terminals connected to the other ends of the plurality of conductive TMVs exposed on the second surface and arranged on the second surface.

5. The O-SIP of claim 1, wherein the inclined surface of the submount has an inclination angle of 80 to 90 degrees on the lower surface.

6. (canceled)

7. An optical module comprising:
an optical system-in-package (O-SIP) having an edge-type light-emitting laser diode emitting an optical signal; and
a planar light circuit (PLC) provided with a grating coupler mounted on a first surface of the O-SIP and placed in a position opposite to the edge-type light-emitting laser diode to receive an optical signal emitted from the edge-type light-emitting laser diode, wherein
the O-SIP comprises:
a mold body having the first surface and a second surface which are flat on an upper portion and a lower portion of the mold body, respectively;
a submount molded inside the mold body and having a side surface having an inclined surface;
an edge-type light-emitting laser diode molded inside the mold body and mounted on the inclined surface of the submount to emit an optical signal to the first surface; and
a redistribution layer formed on the first surface of the mold body and connected to a plurality of external connection terminals to electrically connect the edge-type light-emitting laser diode to the outside.

8. The optical module of claim 6, wherein, when the optical signal emitted from the edge-type light-emitting laser diode is incident on the grating coupler of the PLC, the inclined surface of the submount has an inclination angle of 82 degrees with respect to the lower surface, wherein
the PLC comprises:
a flat body made of silicon photonics;
a grating coupler arranged inside the flat body facing the edge-type light-emitting laser diode to receive the light emitted from the edge-type light-emitting laser diode; and
a waveguide arranged inside the flat body and having one end connected to the grating coupler.

9. An optical module comprising:
an optical system-in-package (O-SIP) having an edge-type light-emitting laser diode emitting an optical signal;
a printed circuit board (PCB) having a lower surface on which the O-SIP is mounted, and having a light passage window forming an optical path when an optical signal is generated in a vertical direction from a light-emitting unit at a portion corresponding to the light-emitting unit of the edge-type light-emitting laser diode; and
a planar light circuit (PLC) provided with a grating coupler mounted on an upper surface of the O-SIP and placed in a position opposite to the edge-type light-emitting laser diode to receive, through the light passage window, an optical signal emitted from the edge-type light-emitting laser diode.

10. The optical module of claim 9, further comprising a micro-lens integrally formed on an upper surface of the O-SIP so as to focus the optical signal emitted from the edge-type light-emitting laser diode.

11.-20. (canceled)

21. The optical module of claim 9, wherein the optical system-in-package (O-SIP) comprising:
a mold body having the first surface and a second surface which are flat on an upper portion and a lower portion of the mold body, respectively;
a submount molded inside the mold body and having a side surface having an inclined surface;
an edge-type light-emitting laser diode molded inside the mold body and mounted on the inclined surface of the submount to emit an optical signal to the first surface; and
a redistribution layer formed on the first surface or on the second surface of the mold body and connected to a plurality of external connection terminals to electrically connect the edge-type light-emitting laser diode to the outside.

22. The optical module of claim 21, wherein the submount further comprises a metal electrode extending from the inclined surface to the upper surface, and the edge-type light-emitting laser diode has an electrode terminal connected to the metal electrode.

23. The optical module of claim 21, further comprising:
a driver IC unit molded inside the mold body to expose a bonding pad on the first surface and driving the edge-type light-emitting laser diode; and
a heat dissipation metal structure having an upper surface in surface contact with a lower surface of the driver IC and a lower surface exposed to the second surface.

24. The optical module of claim 21, further comprising:
a plurality of conductive through mold vias (TMVs) through which one end is connected to a connection wiring of the redistribution layer and the other end passes through the mold body and is exposed to the second surface, and
a plurality of external connection terminals connected to the other ends of the plurality of conductive TMVs exposed on the second surface and arranged on the second surface.

25. The optical module of claim 21, wherein the inclined surface of the submount has an inclination angle of 80 to 90 degrees on the lower surface.
